(19) United States
(12) Patent Application Publication
(10) Pub. No.: US 2012/0312947 A1
(43) Pub. Date: Dec. 13, 2012

(54) ADJUSTABLE MOUNT FOR SUPPORTING SOLAR PANEL AND ANGLE-ADJUSTING METHOD THEREFOR

(76) Inventors: Ching-Chieh Shih, Hsin-Chu (TW); Tung-I Yen, Hsin-Chu (TW); Pei-Ling Chiang, Hsin-Chu (TW)

(21) Appl. No.: 13/224,334

(22) Filed: Sep. 2, 2011

(30) Foreign Application Priority Data
Jun. 7, 2011 (TW) 100119757

(51) Int. Cl. H01L 23/12; B23P 17/00

(52) U.S. Cl. 248/291.1; 29/402.01

(57) ABSTRACT

An adjustable mount for supporting solar panel and an angle-adjusting method therefor are disclosed. The adjustable mount includes a frame, an angle-adjusting device, and a side support. At least one solar panel can be mounted on the frame. The angle-adjusting device is disposed on the frame and includes an angle index part for providing finite angle positions. The side support is connected to the frame through the angle-adjusting device. A relative rotation angle of the side support and the frame can be adjusted by engaging the side support and the angle index part. The relative rotation angle corresponds to one of the finite angle positions. Therefore, the invention can mount the solar panel in different angles based on various demands, which overcomes the poor utilization of solar energy by the solar panel mounted in an immovable angle in the prior art.

### BACKGROUND OF THE INVENTION

1. Field of the Invention

The invention relates to an adjustable mount and an angle-adjusting method, and especially relates to an adjustable mount providing a plurality of fixing angles for solar panels and an angle-adjusting method therefor.

2. Description of the Prior Art

As the light-emitting power of Light-Emitting Diode (LED) is improving, the solar power generation has entered commercial operation. Because a solar panel performs photovoltaic conversion with sunlight, the intensity of the sunlight received by the solar panel becomes important. In a system design of immovable receiving angle, a supporting mount thereof provide only an immovable supporting angle for solar panels. So the angle is normally designed to be an optimum angle of inclination in some locality so that the solar panels can receive most solar energy. However, the optimum angle of inclination for every locality is not the same. The supporting mount providing only one immovable angle for supporting cannot meet the requirements of optimum angle of inclination for every locality. In other words, the solar panels on the supporting mount with single immovable inclination utilize sunlight poorly in some localities, leading to solar energy loss. If the supporting mount is customized for each locality, the cost of manufacturing and stock management will increase.

### SUMMARY OF THE INVENTION

An objective of the invention is to provide an adjustable mount for supporting solar panel. The adjustable mount provides a plurality of supporting angles by use of angle-adjusting device so that solar panels disposed on the adjustable mount can receive sunlight in a better angle.

The adjustable mount of the invention includes a frame, an angle-adjusting device, and a side support. The frame is used for fixing at least one solar panel. The angle-adjusting device is disposed on the frame and includes an angle index part for providing finite angle positions. The side support is connected to the frame through the angle-adjusting device. Therein, a relative rotation angle of the side support and the frame is capable of being adjusted by engaging the side support and the angle index part. The relative rotation angle corresponds to one of the finite angle positions. Thereby, the adjustable mount can provide proper relative rotation angles for choice for various operation localities, so that the solar panel can receive sunlight in a better angle to enhance the utilization of the received sunlight.

Another objective of the invention is to provide an angle-adjusting method for the adjustable mount of the invention. The angle-adjusting method is to use the angle-adjusting device to adjust the disposition angle of the solar panel so that the solar panel can receive sunlight in a better angle.

The angle-adjusting method of the invention uses the adjustable mount of the invention. The angle-adjusting method is to adjust the relative rotation angle of the side support and the frame by engaging the side support and the angle index part. Therein, the relative rotation angle corresponds to one of the finite angle positions. Thereby, the angle-adjusting method is to be able to adjust the relative rotation angle for various operation localities, so that the solar panel can receive sunlight in a better angle to enhance the utilization of the received sunlight.

In sum, the adjustable mount and the angle-adjusting method therefor of the invention can provide finite angles of fixing the solar panel. During the disposing of the adjustable mount, the invention adjusts the relative rotation angle of the side support and the frame by engaging the side support and the angle index part, so as to meet requirements of optimum angle of inclination for different operation localities, which solves the problem that the supporting mount with single immovable angle cannot be applied to different localities effectively in the prior art.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram illustrating a partially-exploded view of an adjustable mount of a preferred embodiment according to the invention.

FIG. 2 is a schematic diagram illustrating a side view of the adjustable mount in FIG. 1.

FIG. 3 is a sectional view of a bottom bar of the adjustable mount in FIG. 1.

FIG. 4 is a flow chart of an angle-adjusting method for the adjustable mount in FIG. 1 according to an embodiment.

FIG. 5 is a schematic diagram illustrating a partially-exploded view of an adjustable mount of another preferred embodiment according to the invention.

FIG. 6 is a flow chart of an angle-adjusting method for the adjustable mount in FIG. 4 according to an embodiment.

### DETAILED DESCRIPTION

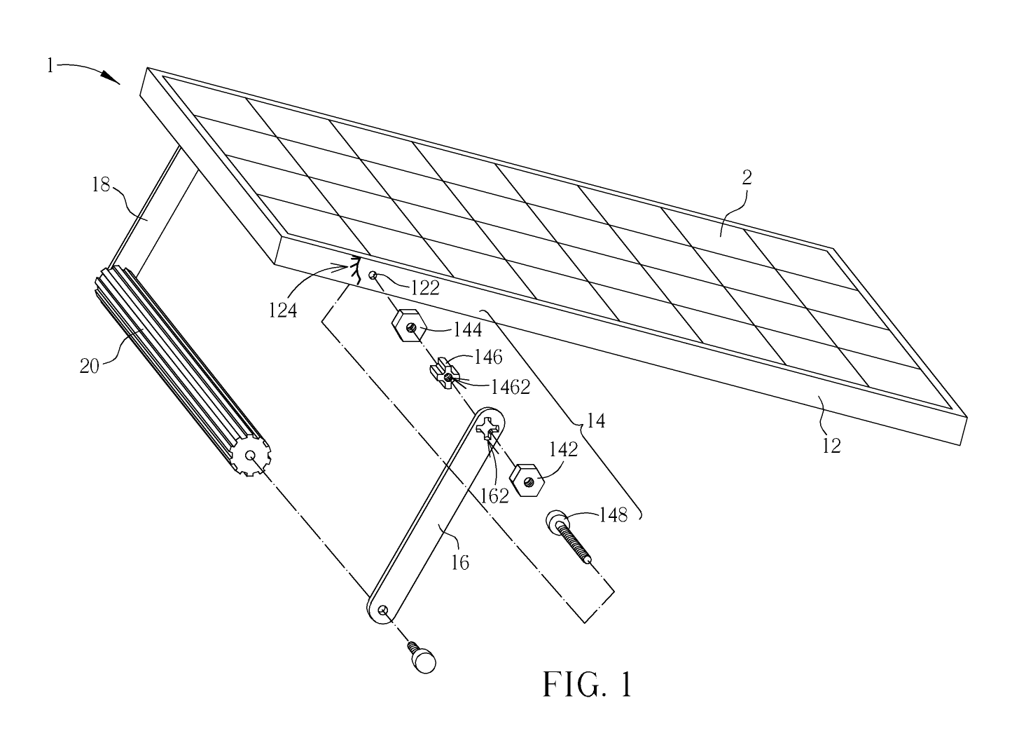

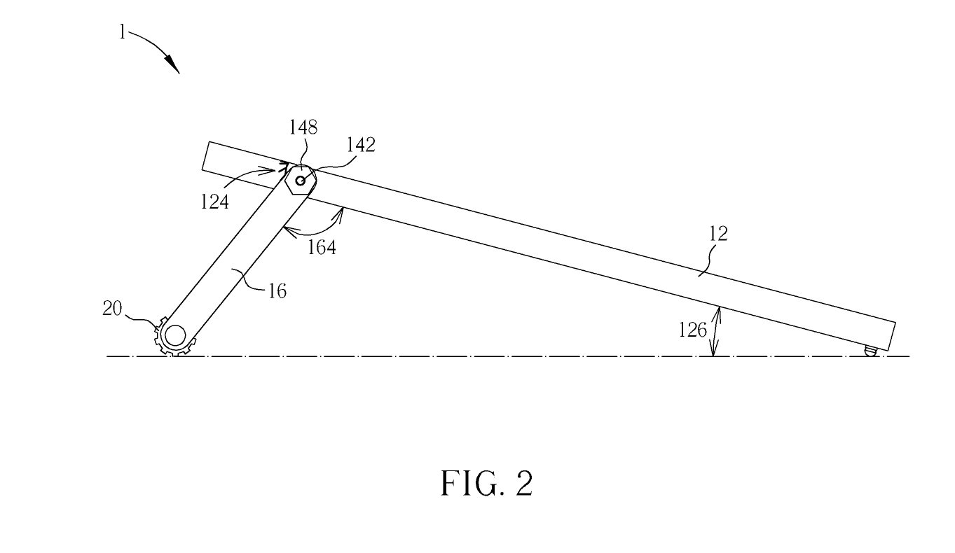

Please refer to FIG. 1 and FIG. 2. FIG. 1 is a schematic diagram illustrating a partially-exploded view of an adjustable mount 1 of a preferred embodiment according to the invention; therein, there are solar panels 2 fixed on the adjustable mount 1. FIG. 2 is a schematic diagram illustrating a side view of the adjustable mount 1. The adjustable mount 1 includes a frame 12, an angle-adjusting device 14, a first side support 16, a second side support 18, and a bottom bar 20. The solar panels 12 are fixed on the frame 12. The first side support 16 and the second side support 18 are connected to two ends of the bottom bar 20 oppositely and pivotally connected to two sides of the frame 12, for supporting the frame 12. Therein, the angle-adjusting device 14 is disposed on the frame 12. The first side support 16 is connected to the frame 12 through the angle-adjusting device 14. In the embodiment, only the second side support 18 is directly pivotally connected to the frame 12, but the invention is not limited to it. In practice, the second side support 18 can also be connected to the frame 12 through the angle-adjusting device 14, which enhances the stability of the supporting.

In the embodiment, the angle-adjusting device 14 includes a bolt 142, a first nut 144, an angle index part 146, and a second nut 148. The frame 12 has a through hole 122. The bolt 142 passes through the through hole 122 from the inside of the frame 12. The first nut 144 is screwed tightly on the bolt 142 to be fixed on the frame 12. The angle index part 146 is a gear, sleeved on the bolt 142 to be fixed. The first side support 16 has a teeth-shaped through hole 162 corresponding to the angle index part 146, for engaging with the angle index part 146. The above fixing way can be performed by screwing the second nut 148 on the bolt 142 to pack the angle index part 146. In this case, the second nut 148 can be a nut capable of passing through the teeth-shaped through hole 162 so that the first side support 16 can be sleeved directly on the angle index part 146. Or the angle index part 146 thereon forms an inner thread 1462, and then the above fixing way can be performed by screwing the angle index part 146 on the bolt 142 through the inner thread 1462. Or the above fixing way can be performed by fixing the angle index part 146 on the bolt 142 by use of other adhering or soldering. The angle-adjusting device 14 provides finite angle positions by use of the angle index part 146. In practice, the angle position means the status of the engagement angle of the first side support 16 and the angle index part 146 and influences the relative rotation angle 164 of the first side support 16 and the frame 12, but not directly in a numerical conversion of a numerical equation. This is because the relative rotation angle 164 is also influenced by the relative disposition angle of the angle index part 146 and the frame 12. In practice, the above relations can be quantified so that the angle position can be converted into a corresponding value of the relative rotation angle 164; however, the invention is not limited to it. In the embodiment, the angle index part 146 has four teeth, so the angle index part 146 can provide four angle positions logically; however, in practice, two of the teeth are used for positioning. The relative rotation angle 164 of the first side support 16 and the frame 12 can be adjusted by engaging the first side support 16 and the angle index part 146; in other words, it is adjusted by engaging the teeth-shaped through hole 162 and the angle index part 146 in different rotation angles. After adjusted, the relative rotation angle 164 corresponds to one of the finite angle positions.

It is added that, the angle index part 146 uses gear structure so that the junction strength of the angle index part 146 and the first side support 16 is stronger than that of a common fitting of shaft and hole, so as to obtain a stable supporting angle. Furthermore, if the angle index part 146 is screwed tightly on the bolt 142 through the inner thread 1462, the second nut 148 can be a nut larger than the teeth-shaped through hole 162 lest the first side support 16 should depart from the angle index part 146. In addition, the frame 12 thereon forms an angle scale 124 close to the angle-adjusting device 14. The angle scale 124 includes a plurality of marks (shown by bold lines) corresponding to the finite angle positions; it is conducive to setting the relative rotation angle 164 during the engagement of the first side support 16 and the angle index part 146. It is added more that, referring to FIG. 2, a disposition angle for the solar panels 2 generally means the included angle 126 of the frame 12 and the ground (shown by a chain line). Although the above illustration of the invention is not based on the included angle 126, a person of ordinary skill in the art can obtain needed information through simple geometric conversion according to the actual size of a product; therefore, it is not described in detail herein.

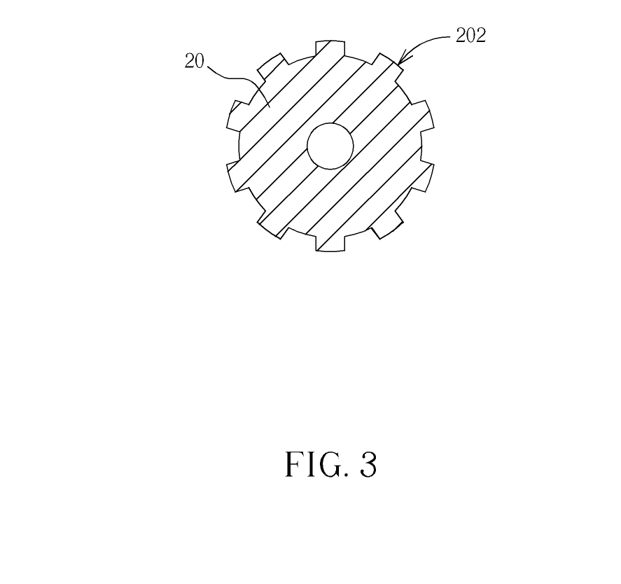

Please refer to FIG. 3, which is a sectional view of the bottom bar 20, the section position of which is substantially shown as the line X-X in FIG. 1. The bottom bar 20 has an anti-skid surface structure 202. In the embodiment, the anti-skid surface structure 202 is a teeth-shaped surface and can enhance the friction force by the ground. In practice, the anti-skid surface structure of the invention is not limited to the square-teeth-shaped surface as shown in FIG. 3. For example, a taper-teeth-shaped surface or a roughness surface is also able to enhance the friction force by the ground.

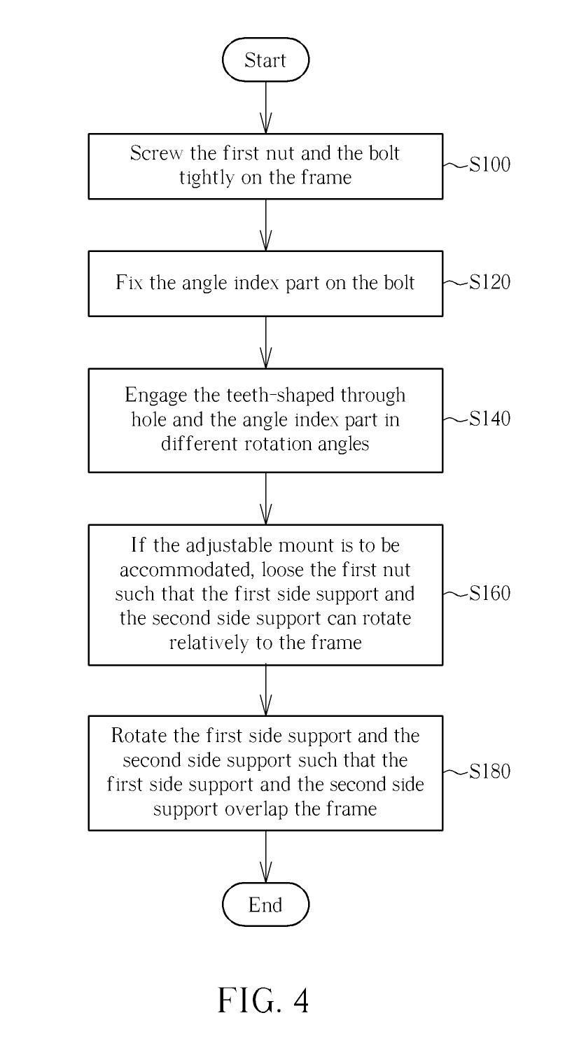

Please refer to FIG. 4, which is a flow chart of an angle-adjusting method for the adjustable mount 1 according to an embodiment. The angle-adjusting method is first to screw the first nut 144 and the bolt 142 tightly on the frame 12, shown as the step S100, and then to fix the angle index part 146 on the bolt 142, shown as the step S120. The fixing way of the angle index part 146 can be performed by packing with the second nut 148, by the inner thread 1462 formed on the angle index part 146, or by use of other adhering or soldering; the related description therefor is described in the abovementioned and is no longer repeated. The angle-adjusting method is then to engage the teeth-shaped through hole 162 and the angle index part 146 indifferent rotation angles for adjusting the relative rotation angle 164 so as to obtain the needed relative rotation angle 164, shown as the step S140; therein the adjusted relative rotation angle 164 corresponds to one of the finite angle positions. If the adjustable mount 1 is to be accommodated, the angle-adjusting method is to loose the first nut 144 such that the first side support 16 and the second side support 18 can rotate relatively to the frame 12, shown as the step S160, and then to rotate the first side support 16 and the second side support 18 such that the first side support and the second side support 18 overlap the frame 12 for accommodation, shown as the step S180.

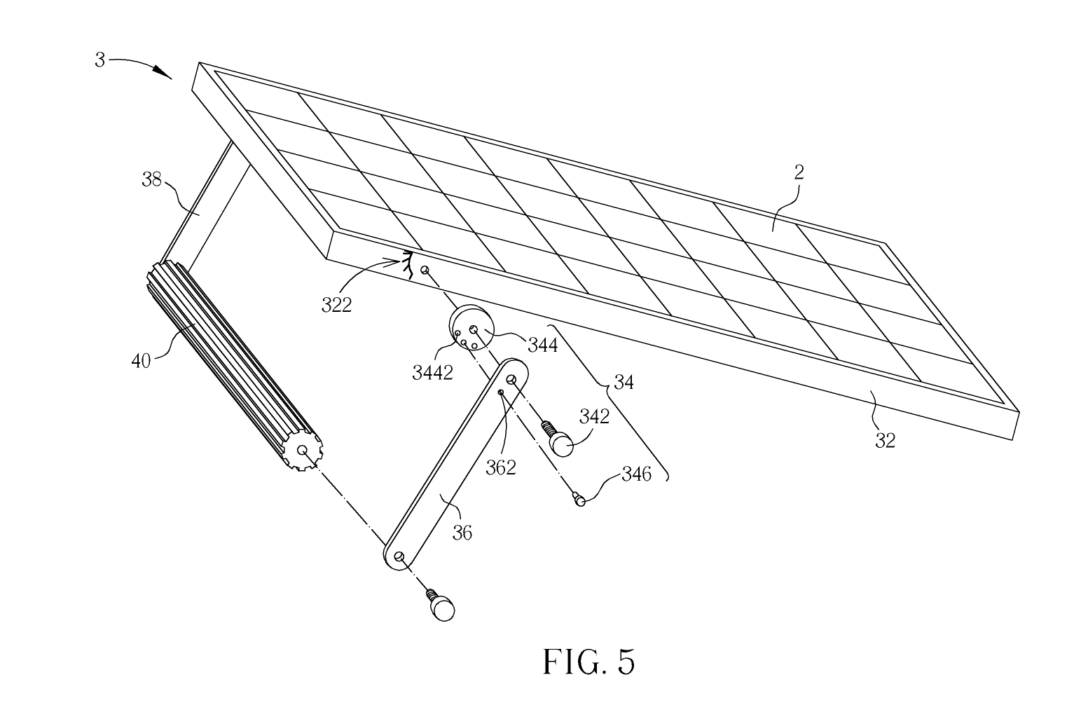

Please refer to FIG. 5, which is a schematic diagram illustrating a partially-exploded view of an adjustable mount 3 of another preferred embodiment according to the invention; therein, there are solar panels 2 fixed on the adjustable mount 3. The adjustable mount 3 includes a frame 32, an angle-adjusting device 34, a first side support 36, a second side support 38, and a bottom bar 40. The adjustable mount 3 and the adjustable mount 1 are similar in structure. The following description is focused on the difference therebetween. Other related descriptions of the adjustable mount 3 refer to the above-mentioned description and are no longer described. The angle-adjusting device 34 of the adjustable mount 3 includes a bolt 342, an angle index part 344, and a pin 346. The angle index part 344 is an index plate fixed on the frame 32 and having a plurality of first positioning holes 3442. The fixing way therefor can be performed by use of a screw to screw the angle index part 344 tightly on the frame 32 with or by use of adhering or soldering to fix the angle index part 344 on the frame 32. The bolt 342 screws the first side support 36 tightly on the frame 32. The first side support 36 has a second positioning hole 362. The relative rotation angle (referring to the relative rotation angle 164 shown in FIG. 2) of the first side support 36 and the frame 32 can be adjusted by inserting the pin 346 into the second positioning hole 362 and one of the first positioning holes 3442.

Similarly, the angle-adjusting device 34 can provide finite angle positions by use of the first positioning hole 3442 of the angle index part 344. In principle, each angle position corresponds to one of the first positioning holes 3442. A user can insert the pin 346 into the second positioning hole 362 and any of the first positioning holes 3442 to achieve the purpose of adjusting the relative rotation angle. In the embodiment, the frame 32 thereon forms an angle scale 322 close to the angle-adjusting device 34. The angle scale 322 includes a plurality of marks (shown by bold lines) corresponding to the finite angle positions. During rotating the first side support 36, the first side support 36 can be aligned with one of the marks for the convenience of the user to insert the pin 346 into the second positioning hole 362 and the corresponding first positioning hole 3442, so as to perform the adjustment of the relative rotation angle.

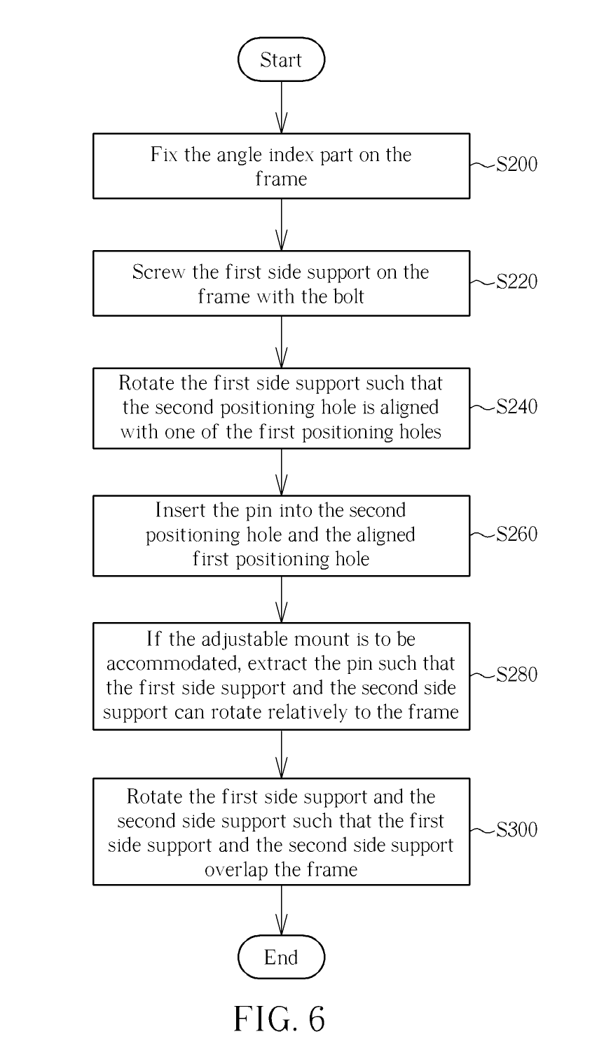

Please refer to FIG. 6, which is a flow chart of an angle-adjusting method for the adjustable mount 3 according to an embodiment. The angle-adjusting method is first to fix the angle index part 344 on the frame 32, shown as the step S200, and then to screw the first side support 36 on the frame 32 with the bolt 342, shown as the step S220. At this moment, it is unnecessary for the blot 342 to screw the first side support 36 tightly, so that the first side support 36 is capable of rotating relatively to the frame 32. Then, the angle-adjusting method is to rotate the first side support 36 such that the second positioning hole 362 is aligned with one of the first positioning holes 3442, shown as the step S240, and then to insert the pin 346 into the second positioning hole 362 and the aligned first positioning hole 3442 so as to obtain the needed relative rotation angle (referring to the relative rotation angle 164 shown in FIG. 2), shown as the step S260. In practice, there is the angle scale 322 formed on the frame 32 of the adjustable mount 3, so before the step S240, the angle-adjusting method maybe to rotate the first side support 36 to align one of the marks in advance. Then, in the step S240, the angle-adjusting method is to align the second positioning hole 362 with the first positioning hole 3442 corresponding to the mark quickly and precisely. If the adjustable mount 3 is to be accommodated, the angle-adjusting method is to extract the pin 346 such that the first side support 36 and the second side support 38 can rotate relatively to the frame 32, shown as the step S280, and then to rotate the first side support 36 and the second side support 38 such that the first side support 36 and the second side support 38 overlap the frame 32 for accommodation, shown as the step S300.

As discussed above, the adjustable mount and the angle-adjusting method therefor of the invention can provide finite angles of fixing the solar panel by use of the angle-adjusting device. During the disposing of the adjustable mount, the invention adjusts the relative rotation angle of the side support and the frame by engaging the side support and the angle index part, so as to meet requirements of optimum angle of inclination for different operation localities so that the solar panel can receive sunlight in a better angle to enhance the utilization of the received sunlight for enhance the utilization of the sunlight, which solves the problem that the supporting mount with single immovable angle cannot be applied to different localities effectively in the prior art.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An adjustable mount for supporting solar panel, comprising:
a frame, for fixing at least one solar panel;
an angle-adjusting device, disposed on the frame, the angle-adjusting device comprising an angle index part for providing finite angle positions; and
a first side support, connected to the frame through the angle-adjusting device;
wherein a relative rotation angle of the first side support and the frame is capable of being adjusted by engaging the first side support and the angle index part, and the relative rotation angle corresponds to one of the finite angle positions.

2. The adjustable mount of claim 1, wherein the angle-adjusting device further comprises a bolt and a first nut, the angle index part is a gear, the first nut is screwed tightly on the bolt to be fixed on the frame, the angle index part is fixed on the bolt, the first side support has a teeth-shaped through hole engaged with the angle index part, and the relative rotation angle is capable of being adjusted by engaging the teeth-shaped through hole and the angle index part in different rotation angles.

3. The adjustable mount of claim 2, wherein the angle-adjusting device further comprises a second nut screwed tightly on the bolt to fix the angle index part.

4. The adjustable mount of claim 2, wherein the angle index part has an inner thread, and the angle index part is screwed tightly on the bolt by the inner thread.

5. The adjustable mount of claim 1, wherein the angle-adjusting device further comprises a bolt and a pin, the angle index part is an index plate mounted on the frame and having a plurality of first positioning holes, the first side support is screwed on the frame with the bolt, the first side support has a second positioning hole, and the relative rotation angle is capable of being adjusted by inserting the pin into the second positioning hole and one of the first positioning holes.

6. The adjustable mount of claim 1, wherein the frame has an angle scale close to the angle-adjusting device, and the angle scale comprises a plurality of marks corresponding to the finite angle positions.

7. The adjustable mount of claim 1, further comprising a bottom bar connected to the first side support for supporting the frame.

8. The adjustable mount of claim 7, wherein the bottom bar has an anti-skid surface structure.

9. The adjustable mount of claim 8, wherein the anti-skid surface structure is a roughness surface or a teeth-shaped surface.

10. The adjustable mount of claim 8, further comprising a second side support pivotally connected to the frame relatively to the first and connected to the bottom bar.

11. An angle-adjusting method for the adjustable mount of claim 1, the angle-adjusting method comprising the following step:
(a) engaging the first side support and the angle index part to adjust the relative rotation angle, wherein the relative rotation angle corresponds to one of the finite angle positions.

12. The angle-adjusting method of claim 11, wherein the angle-adjusting device further comprises a bolt and a first nut, the angle index part is a gear, the first nut is screwed tightly on the bolt to be fixed on the frame, the angle index part is fixed on the bolt, the first side support has a teeth-shaped through hole, and the step (a) is performed by the following step:
(a1) engaging the teeth-shaped through hole and the angle index part in different rotation angles.

13. The angle-adjusting method of claim 12, wherein the angle-adjusting device further comprises a second nut, and the step (a) further comprises the following step:
(a2) screwing the second nut tightly on the bolt to fix the angle index part.

14. The angle-adjusting method of claim 12, further comprising the following steps:
(b) loosing the first nut; and
(c) rotating the first side support such that the first side support and the frame overlap for accommodating.

15. The angle-adjusting method of claim 11, wherein the angle-adjusting device further comprises a bolt and a pin, the angle index part is an index plate mounted on the frame and having a plurality of first positioning holes, the first side support is screwed on the frame with the bolt, the first side support has a second positioning hole, and the step (a) is performed by the following steps:
(a3) rotating the first side support such that the second positioning hole is aligned with one of the first positioning holes; and
(a4) inserting the pin into the second positioning hole and the aligned first positioning hole.

16. The angle-adjusting method of claim 11, wherein the frame has an angle scale close to the angle-adjusting device, the angle scale comprises a plurality of marks corresponding to the finite angle positions, and the step (a) further comprises the following step:
(a5) rotating the first side support to be aligned with one of the marks.
